(19) United States
(12) Patent Application Publication
(10) Pub. No.: US 2007/0019254 A1
(43) Pub. Date: Jan. 25, 2007

(54) Closed-loop color calibration with perceptual adjustment

(76) Inventor: Huanzhao Zeng, Vancouver, WA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/186,325

(22) Filed: Jul. 21, 2005

(51) Int. Cl. G03F 3/08; G06F 15/00

(52) U.S. Cl. 358/504; 358/1.9; 358/518

(57) ABSTRACT

Disclosed are embodiments of a system and method for color calibration. The method includes printing an image using target image data. The printed image is scanned. Scanned image data is generated from the scanned image. A three-dimensional relative colorimetric table is generated from a comparison of the target image data with the scanned image data. Perceptual color adjustment, including gamut mapping, is performed on the scanned image data to form perceptually adjusted and gamut adjusted data. The three-dimensional relative colorimetric table and the perceptually adjusted and gamut adjusted data are applied to the system to achieve closed-loop copier color calibration with perceptual enhancement.

### BACKGROUND

The present invention relates generally to the field of closed loop color calibration, and more particularly to a system and method of closed loop color calibration with perceptual adjustment.

Many image-processing machines, such as MFP (multi-function printer) and color copy machines, experience problems with color consistency and stability over their life cycles. Colors produced by such machines can drift over time as machines are used. Colors change slightly because of several factors. For example, the colorant (ink or toner) used in a machine can change because of chemical factors, or the actual formulation of the colorant used can change over time. The media to which the image is transferred may also be slightly different from what was used originally for the color calibration on the machine. Furthermore, the scanner color shift changes the digital signal to drive the printer, and therefore the output color. In addition, various types of mechanical issues and environmental issues, such as temperature and humidity, will change the color.

A copier (or copy machine, or MFP) typically includes a source device (such as a scanner) configured to scan colors and an output device (such as a printer) configured to produce output colors. For such machines, closed-loop color calibration (CLCC) is typically used to help with color consistency and stability. With such a calibration process, the machine prints a pre-defined target, which includes some color patches, typically from a few dozen to a few hundred such color patches. Then these printed targets are scanned into the machine. After the scanned image is loaded into the machine, and an algorithm inside the machine compares the RGB values of this scanned image with corresponding RGB values used to print the target. Differences in the RGB values of the scanned image and the printed image can be used to make adjustment such that the machine copies colors closer to the original. However, different printing conditions (media, inks, printing technologies, etc.) between the original hardcopy and the reproduced hardcopy prevent making an exact match. Furthermore, exact matching does not always produce the most preferable color results. Some color preference adjustments and gamut adaptation can improve customer satisfaction for the copy machine.

For these and other reasons, a need exists for the present invention.

### SUMMARY

Exemplary embodiments of the present invention include a system and method for color calibration. The method includes printing an image using target image data. The printed image is scanned. Scanned image data is generated from the scanned image. A three-dimensional relative calorimetric table is generated from a comparison of the target image data with the scanned image data. Perceptual color adjustment, including gamut mapping, is performed on the scanned image data to form perceptually adjusted and gamut adjusted data. The three-dimensional relative calorimetric table and the perceptually adjusted and gamut adjusted data are applied to the system to achieve closed-loop copier color calibration with perceptual enhancement.

### BRIEF DESCRIPTION OF THE DRAWINGS

FIG. 1 illustrates an image processing system with input and output color devices.

FIG. 2 is a flow diagram illustrating a general closed-loop color calibration workflow.

FIG. 3 is a flow diagram illustrating a general color copier for calorimetric matching.

FIG. 4 is a flow diagram illustrating for the color transformation with closed-loop color calibration.

FIG. 5 is an alternative flow diagram illustrating for the color transformation with a closed-loop color calibration.

FIG. 6 is a flow diagram illustrating decoupling a printer three dimensional lookup table into two three dimensional lookup tables according to one embodiment of the present invention.

FIG. 7 is a flow diagram illustrating the data flow of perceptual color adjustment according to one embodiment of the present invention.

FIGS. 8A and 8B illustrate differences in lightness mapping between relative calorimetric mapping and preference mapping according to one embodiment of the present invention.

FIG. 9 illustrates a lightness mapping curve to modify the lightness mapping of the relative calorimetric mapping according to one embodiment of the present invention.

FIG. 10 illustrates an example of the difference between a source gamut and a printer gamut according to one embodiment of the present invention.

FIGS. 11A and 11B illustrate chroma compression for different sized printer and source gamuts according to one embodiment of the present invention.

FIG. 12 illustrates another example of the difference between a source gamut and a printer gamut according to one embodiment of the present invention.

FIG. 13 is a flow diagram illustrating generation of a perceptual color adjustment three-dimensional lookup table or a function according to one embodiment of the present invention.

FIG. 14 is another flow diagram illustrating perceptual matching for copier color flow according to one embodiment of the present invention.

FIG. 15 a flow diagram illustrating a process for closed-loop color calibration with perceptual color adjustment according to one embodiment of the present invention.

### DETAILED DESCRIPTION

In the following Detailed Description, reference is made to the accompanying drawings, which form a part hereof, and in which is shown by way of illustration specific embodiments in which the invention can be practiced. It is to be understood that other embodiments can be utilized and structural or logical changes can be made without departing from the scope of the present invention. The following Detailed Description, therefore, is not to be taken in a limiting sense, and the scope of the present invention is defined by the appended claims.

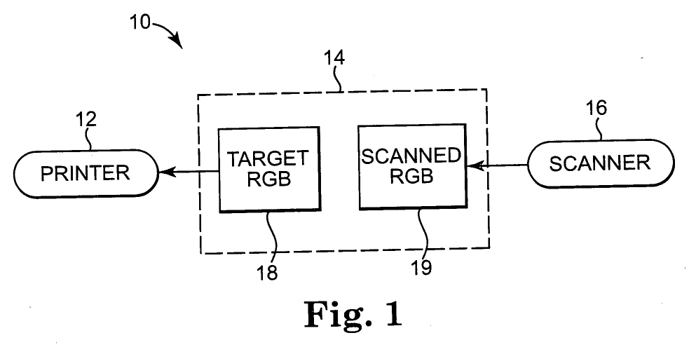

FIG. 1 illustrates image processing system 10. In one example, image processing system 10 includes printer 12, processing device 14 and scanner 16. In one example, image processing system 10 is a color copier machine. As image processing system 10 is used over its life cycle to reproduce color images, it is difficult to maintain color consistency and stability without a recalibration mechanism. In this way, image processing system 10 cannot exactly match an original hardcopy and a reproduced hardcopy without some kind of adjustment.

Thus, processing device 14, of image processing system 10, stores pre-defined target RGB data 18. This target RGB data 18 is used to produce an image via printer 12. Also, scanner 16 is configured to scan the printed image, and produce a set of associated scanned RGB data 19. Target RGB data 18 and scanned RGB data 19 are then compared, and a closed-loop copier color calibration (CLCC) is used to make adjustments based on any differences in target RGB data 18 and scanned RGB data 19.

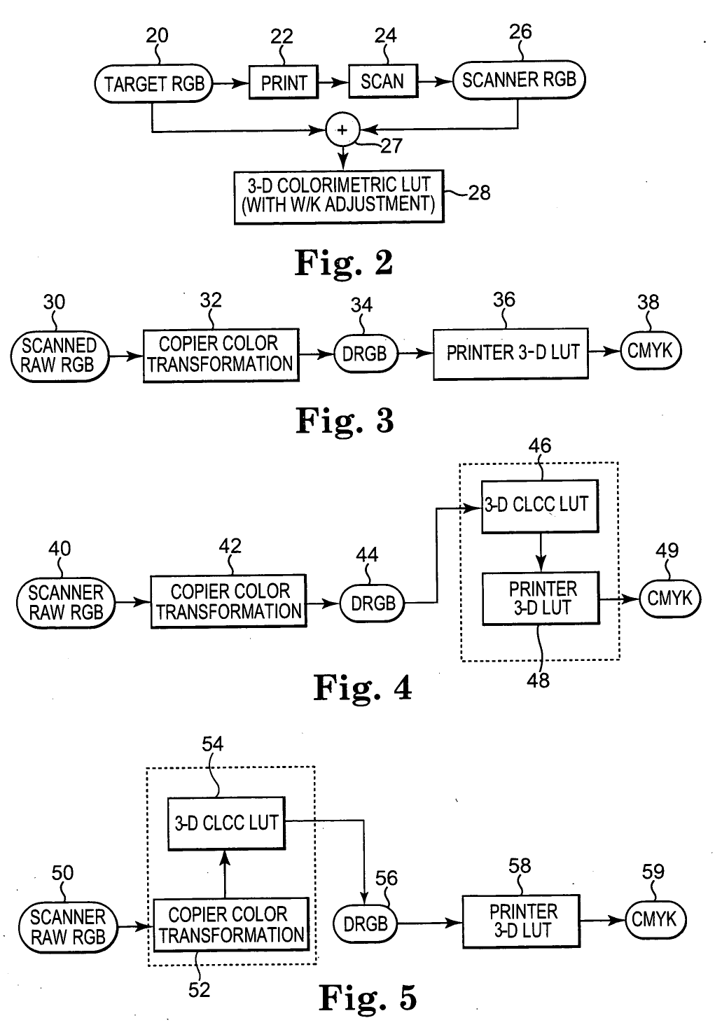

A general process of a closed-loop color calibration in an image processing system, such as can be used in image processing system 10, is illustrated in the flow diagram of FIG. 2. Pre-defined target RGB data 20 is defined and stored in an image processing system. An image is printed with target RGB data 20 using a printer within the image processing system at step 22. Then, a scan of the printed target image is made via a scanner within the image processing system at step 24. Scanner RGB 26 data is produced from the scanned image, and it is stored in the image processing system. The scanner RGB data 26 and target RGB data 20 are then compared at step 27, such that a three-dimensional lookup table, with adjustment, is built at step 28. This three-dimensional lookup table is used to correct the scanner RGB data 26 and adjust RGB color values. With such adjustments, copied hardcopies processed in the image processing system match original hardcopies.

A general process for copier color transformation is then illustrated in the flow diagram of FIG. 3. The scanner of the copier scans in scanned raw RGB data 30. The scanned raw RGB data 30 goes through a copier color transformation at step 32. Typically, copier color transformation is a hardware assisted transformation to perform various adjustments and enhancements. For example, copier color transformation includes text enhancement (for example, darkening any black text where it is not dark enough), color adjustment, image adjustment, and sharpening. In this way, copier color transformation slightly changes the scanner raw RGB data 30, and then it is converted to device RGB data 34. Next, at step 36 a print engine of the copier converts device RGB data 34 into CMYK color space data 38 using a three-dimensional lookup table. This produces printer device color data, such as CMYK data 38, which is appropriate for printing.

A general process for copier color transformation utilizing CLCC is illustrated in the flow diagram of FIG. 4. Similar to the process in FIG. 3, the scanner of the copier scans in scanned raw RGB data 40. The scanned raw RGB data 40 then goes through a copier color transformation at step 42. Again, the copier color transformation process slightly changes the scanner raw RGB data 40 and then converts it back to device RGB data 44. Next, a CLCC lookup table, such as that built in the work flow illustrated in FIG. 2, is added at step 46, before a copier color transformation at step 48. At step 48, a print engine of the copier converts device RGB data 44 into CMYK color space data 49 using a three-dimensional lookup table. This produces printer device color data, such as CMYK data 49, which is appropriate for printing.

In step 46 of the process, the CLCC lookup table is applied to adjust device RGB data 44. In this way, the CCLC lookup table generated from the comparison of scanner RGB data and target RGB data (such as that generated in step 28 in FIG. 2) is used to further adjust device RGB data so that a reproduced hardcopy using this adjusted data more-closely matches an original hardcopy.

In another example, the three-dimensional CLCC lookup table used in step 46 is concatenated with the three-dimensional printer lookup table from step 48. In this way, the two-step process (steps 46 and 48 inside the dashed-rectangle block) will collapse down into a single-step process. Such a single-step process is highly similar to the data flow illustrated in FIG. 3 above. In this alternative workflow example, the printer three-dimensional lookup table is modified after the closed-loop color calibration. If the three-dimensional lookup table generated in FIG. 2 is processed for calorimetric matching, the copier mapping becomes calorimetric matching.

An alternative general process for copier color transformation utilizing CLCC is illustrated in the flow diagram of FIG. 5. This process is similar to that illustrated in FIG. 4, except that the CLCC table is merged with a three-dimensional lookup table in the last step of the scanner color transformation block. In this way, FIG. 5 illustrates the scanner of the copier scanning in scanned raw RGB data 50. The scanned raw RGB data 50 then goes through a copier color transformation at step 52. Then CLCC lookup table, such as that built-in the work flow illustrated in FIG. 2, is added at step 54, as part of the copier color transformation process, thereby producing device RGB data 56. Then, at step 58 a print engine of the copier converts device RGB data 56 into printer device color data, such as CMYK color space data 59 using a three-dimensional lookup table. This produces printer device color data 59, which is appropriate for printing.

Similar to FIG. 4, the two-step process inside the dashed-rectangle block can also be collapsed into one-step processing, such that the three-dimensional lookup table of the copier color transformation step 52 can be concatenated with the three-dimensional CLCC lookup table of step 54, such that the data flow will be the same as FIG. 3.

The CLCC as illustrated in FIG. 2 is reasonable for colorimetric matching between an original hardcopy and a reproduced hardcopy on an image processing system, such as a color copier. If an original hardcopy is printed by the same print engine of the copier with the same print mode, calorimetric matching should produce reasonable color quality. If an original hardcopy is not printed by the same print engine with the same print mode and the same media, however, colorimetric matching alone will not always produce reasonable color quality due to the mismatch between the source gamut and the reproduced gamut. For example, if the gamut from the statistical analysis of different source hardcopies is much smaller than the gamut of the printer, a calorimetric matching will not be able to use the advantage of the larger printer gamut. If the source gamut is larger than the printer gamut, a calorimetric matching may produce too much hard-clipping for high chroma colors of reproduced hardcopies. For example, since many people prefer suntan skin tone, adjusting skin tone colors toward suntan colors instead of producing skin tone colors accurately results in more pleasing result in some cases.

One embodiment of the present invention adds some color preference adjustments in addition to the colorimetric matching between an original hardcopy and a reproduced hardcopy on an image processing system in order to increase color quality. Color adjustment and gamut adaptation can also increase the quality of the color output.

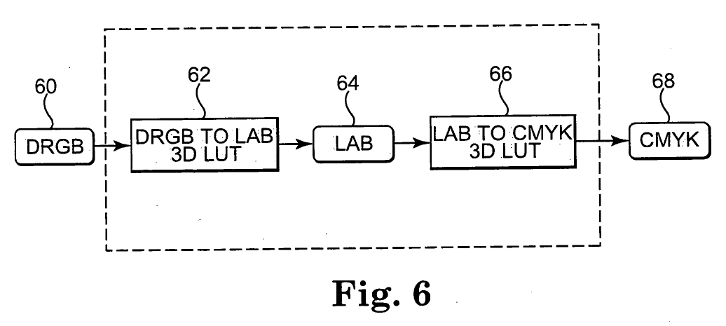

To perform gamut adjustment between the source gamut and the printer gamut, the perceptual adjustment is performed in a mechanism that connects the source gamut to the printer gamut. FIG. 6 illustrates a process for perceptual adjustment in accordance with one embodiment of the present invention. A source gamut in device RGB 60 is provided to such a mechanism illustrated by the dashed rectangle in FIG. 6, in order to produce a printer gamut, in one case CMYK 68.

In one embodiment, the dashed rectangle block in FIG. 6 is the decomposition of the interpolation process using the printer three dimensional lookup table (step 36 of FIG. 3, step 48 of FIG. 4, and step 58 of FIG. 5). During the color mapping process to generate a three dimensional printer lookup table, at step 62 the conversion from device RGB data 60 to LAB data 64 is generated (the characterization from scanner device RGB data to LAB data). Then, at step 66, the conversion from LAB data 64 to CMYK data 66 (the characterization for the printer) is generated. The printer three dimensional lookup table is the concatenation of these two tables. The LAB color space is a luminance-chrominance color space, such as CIELAB, CIELUV, CIECAM97s JAB, CIECAM02 JAB, etc. The perceptual color adjustment can be performed in LAB color space between step 62 and step 66.

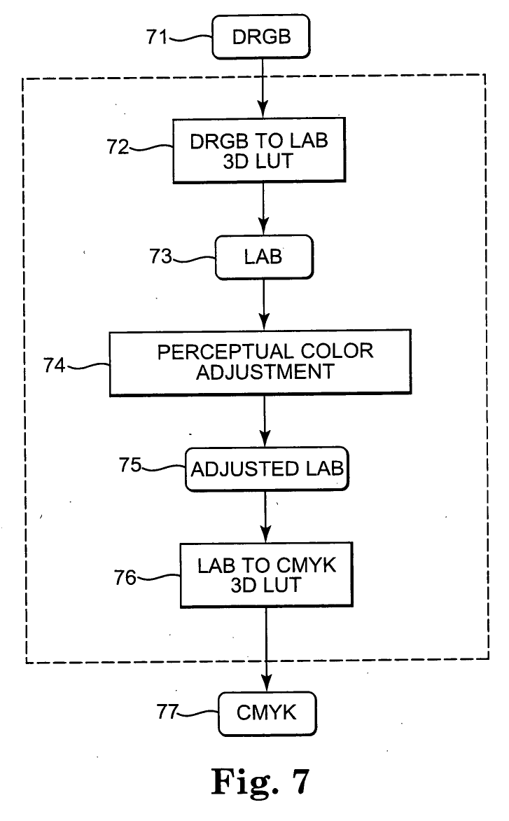

FIG. 7 illustrates the perceptual color adjustment added to adjust colors in LAB color space in accordance with one embodiment of the present invention. Again, at step 72 device RGB data 71 is converted to LAB data 73 (the characterization from scanner device RGB data to LAB data). Next, the color adjustment step 74 can be built as a function to adjust LAB color values, or be built as a three dimensional lookup table to adjust LAB color values through three dimensional interpolation and produce adjusted LAB data 75. Then, at step 76, adjusted LAB data 75 is converted to CMYK data 77.

To perform closed loop color calibration with perceptual adjustment, the perceptual adjustment step 74 in FIG. 7 must be turned off or be set as an identity transformation for colorimetric closed loop color calibration. After the colorimetric-based closed loop color calibration, the perceptual color adjustment step 74 is turned on. With such adjustments, copied hardcopies processed in the image processing system match original hardcopies with color enhancements.

In one embodiment, perceptual color adjustment includes two parts: color preference adjustment and gamut adjustment. The color preference adjustment can include lightness adjustment, chroma adjustment, and hue adjustment.

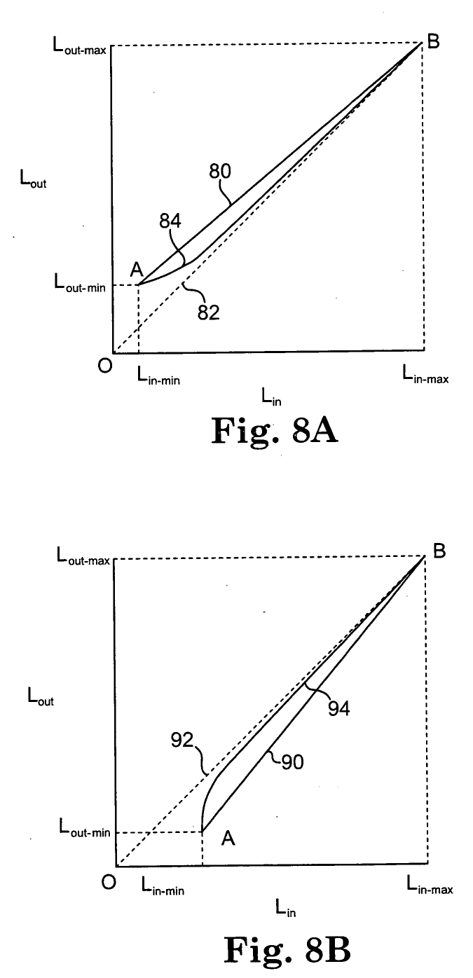

FIGS. 8A and 8B illustrate differences in lightness mapping between relative colorimetric mapping and preference mapping in accordance with one embodiment of the present invention. In FIG. 8A, the black point of an original hardcopy (Lᵢₙ_{_{—}}ₘᵢₙ) is darker than a black point of a printer (Lₒᵤₜ_{_{—}}ₘᵢₙ), and in FIG. 8B the black point of an original hardcopy (Lᵢₙ_{_{—}}ₘᵢₙ) is lighter than a black point of a printer (Lₒᵤₜ_{_{—}}ₘᵢₙ). In this way, contrast adjustment is done with preference mapping thereby producing a better copy. In FIGS. 8A and 8B, A is the black point, B is the white point and O is a point with L=0, that is, a point with no light, or a color patch absorbs all light.

During relative calorimetric mapping (such as in step 28 of FIG. 2) the black point of the source (or scanned raw data) (Lᵢₙ_{_{—}}ₘᵢₙ) is mapped to the black point of the output device (or printer) (Lₒᵤₜ_{_{—}}ₘᵢₙ), and the white point of the scanned data (Lᵢₙ_{_{—}}ₘₐₓ) is mapped to the media white point of the printer (Lₒᵤₜ_{_{—}}ₘₐₓ). Intermediate lightness is then mapped through linear adjustment, which is illustrated by straight line 80 between points A and B in FIG. 8A and illustrated by straight line 90 between points A and B in FIG. 8B). This process is the white and black point adjustment during the construction of a relative calorimetric CLCC lookup table (W/K Adjustment in step 28 of FIG. 2) The dashed lines 82 in FIGS. 8A and 92 in FIG. 8B between points O and B is an identity mapping line. To produce a mapping without black point adjustment, the lightness would be mapped through this line 82 or 92.

However, without black point adjustment, some shadow colors will be clipped to a single output black point if the output black point is lighter than the source black point (see FIG. 8A), or the output black point will not be used if the output black point is darker than source black point (see FIG. 8B). A tradeoff is to have lightness mapping curve similar to the nonlinear curve 84 in FIGS. 8A and 94 in FIG. 8B between points A and B.

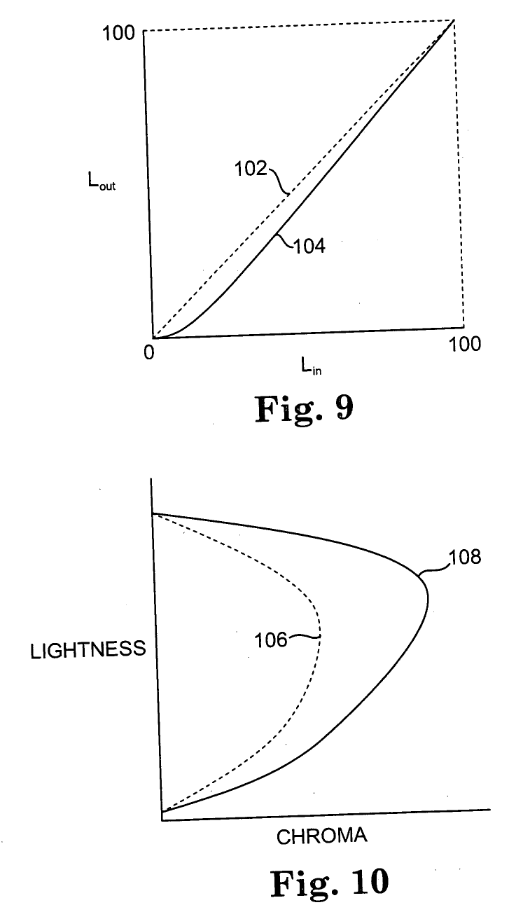

In order to change the linear lightness mapping in the relative calorimetric mapping to behave a nonlinear mapping curve, a preference adjustment as illustrated in FIG. 9 is used to produce a perceptual adjustment. FIG. 9 illustrates a preference adjustment curve 104 in accordance with one embodiment of the present invention. Identity mapping is drawn as a dashed line for comparison. The shaping of the tone curve 104 can be generated by algorithms based on the black points and white points of the original and the reproduced hardcopies. Contrast adjustment can also be added to this mapping curve.

Hue adjustment is another factor that can be considered. For example, the hue angle for skin tone may be adjusted based on the preference of individual person or the preference of race, culture, and so on. Green grass may be shifted slightly toward cyan to produce more greenish grass. Furthermore, chroma can also be adjusted. For business graphics objects (for example, color text, line arts, etc.), the chroma (or saturation) can be boosted slightly.

After lightness, hue angle, and chroma adjustments, gamut mapping may be performed to fit the source gamut into the destination gamut. To perform gamut adjustment (or gamut adaptation), a source gamut and a destination gamut must be generated. The destination gamut is the gamut of the printer in a printer mode and a paper type to be used for copying. The source gamut is the gamut of a specific source hardcopy type to be used for copying, or the gamut from a statistical combination of gamut sets from different original hardcopies.

FIG. 10 illustrates the difference between a source gamut 108 and a printer gamut 106 in accordance with one embodiment of the present invention. In the illustration, gamut mapping is used, rather than simply clipping the source gamut into the destination gamut. This plot illustrates a hue slice of a source gamut 108 (the one with solid curved line) and a destination gamut 106 (the one with dashed curved line), where the horizontal axis is chroma, and the vertical axis is lightness. Typically, the source gamut and destination gamut are different. If the source gamut 108 is a larger gamut than the destination gamut 106, the out-of-gamut colors are clipped to the gamut surface of the destination gamut during the relative calorimetric gamut mapping.

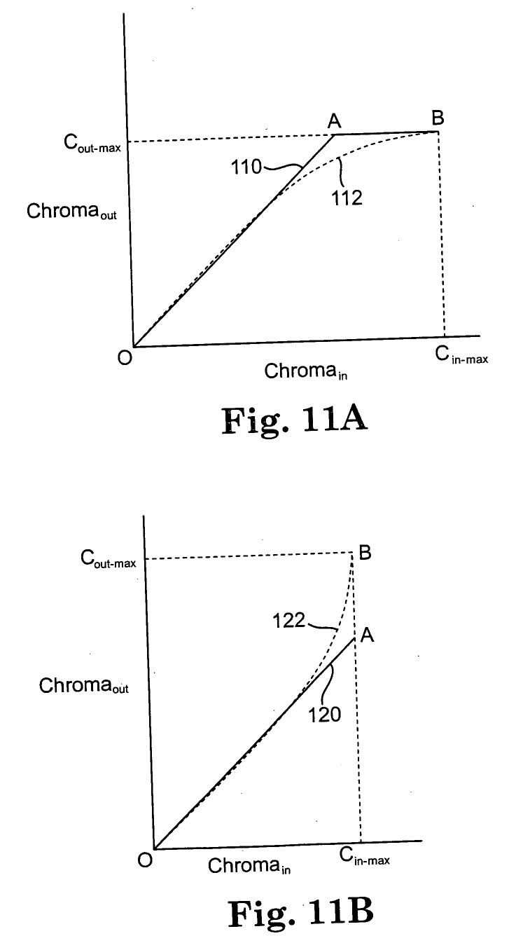

FIG. 11A illustrates chroma clipping or compression in accordance with one embodiment of the present invention. Chromaᵢₙ is the source chroma, and chromaₒᵤₜ is the destination chroma. Here, source chroma that is higher than the maximum destination chroma and is hard clipped to the maximum destination chroma during the colorimetric (or relative calorimetric) gamut mapping, illustrated by straight lines 110 (line segments from point O to point A to point B). The ideal chroma mapping should be similar to curved line 112 (dashed curve from point O to point B in FIG. 11A).

If the source chroma is smaller than the destination chroma in a certain hue angle, the portion of the destination gamut that is out of the source gamut will not be used based on relative calorimetric mapping. In that case, output chroma between point A and point B in FIG. 11B will not be used. The identity mapping line 120 (the straight line from point O to point A) is used for the colorimetric mapping. However, the ideal chroma mapping should be similar to curved line 122 (the dashed curve from point O to point B) for fully using the capability of the printer gamut.

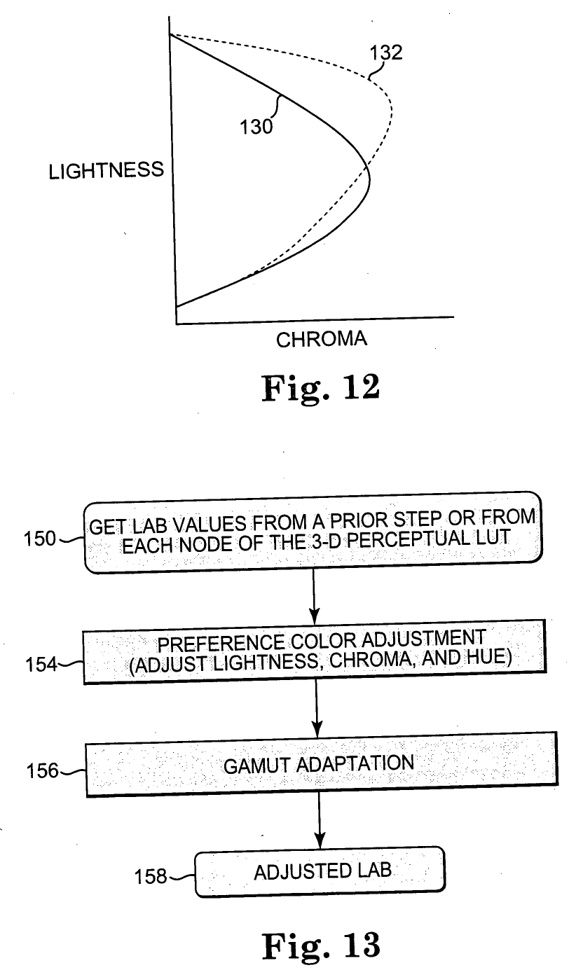

FIG. 12 illustrates a source gamut 132 that is larger than a printer gamut 130 in a certain region, and that is smaller than printer gamut 130 in another region in accordance with one embodiment of the present invention. A more sophisticated gamut mapping method can be used for this kind of gamut differences. However, since the source gamut is usually a fuzzy set (that is, it cannot be generated accurately, or it is the statistical result of many gamut sets), an accurately gamut mapping method to fit a source gamut to a destination gamut is usually not needed.

FIG. 13 illustrates a process to generate a color adjustment three-dimensional lookup table or to process each LAB values come from a step before the perceptual color adjustment in accordance with one embodiment of the present invention. At step 150, LAB values from a prior step or from each node of the three-dimensional perceptual lookup table are obtained. Next, at step 154 preference color adjustment is made in LAB or LCH color space. The lightness, chroma, and hue adjustments are performed in this step. Then, gamut adaptation is performed at step 156. A pre-defined source gamut and a printer gamut stored in the system are used for gamut compression or expansion. Finally, adjusted LAB values are obtained at step 158.

In some embodiments, the perceptual adjustment is pre-built as a lookup table, and in other embodiments, it is generated in real time based on the information of the source hardcopy, the information of the scanner, and the information of the printer, and user preference. In one embodiment, the perceptual adjustment includes performing a perceptual mapping with gamut adaptation (to adapt the source to the printer gamut) and to adjust the printer table.

In one practical example, CLCC is performed for a copier using a type of inkjet photo media for an inkjet copier. Then, a photographic image is copied on a photo paper (AgX). Because a scanner responds differently to AgX paper/dyes and the inkjet photo paper/inks, some color adjustment can improve the color quality. Because the gamut of the source and the gamut of the destination are different, gamut adjustment improves the result. Preference adjustment further improves the color quality.

The perceptual CLCC process is divided into two steps: colorimetric CLCC (see FIGS. 2, 4, and 5), and perceptual color adjustment (see FIG. 7). For colorimetric CLCC without perceptual color adjustment, the two three-dimensional lookup tables 62 and 66 in FIG. 6 are merged into a single three-dimensional lookup table for the transformation for DRGB to CMYK. The dashed rectangle in FIG. 6 is collapsed into a single step, which is step 36 in FIG. 3, step 48 in FIG. 4, or step 58 in FIG. 5.

During perceptual CLCC process, a calorimetric CLCC lookup table is first generated without perceptual color adjustment (turning off perceptual color adjustment or set it to identity transformation). Then a perceptual color transformation function is established, or a three-dimensional perceptual lookup table is generated, or a pre-built perceptual lookup table is selected. Then, the process inside the dashed rectangle in FIG. 7 can be merged into a single three-dimensional lookup table for the transformation from DRGB to CMYK. The color transformation workflow becomes the same as the colorimetric CLCC in FIGS. 4 and 5. The only difference is that the printer three-dimensional lookup table (step 48 of FIG. 4 or step 58 of FIG. 5) is modified through preference and gamut adjustment.

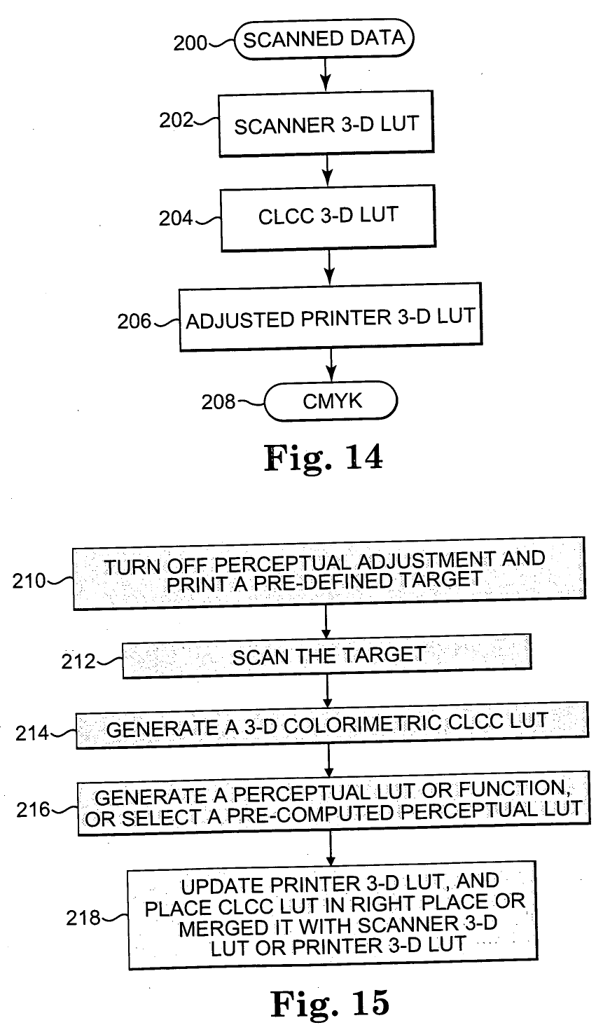

In an alternative embodiment, the color transformation lookup tables from the scanner, CLCC, and the printer (including perceptual color adjustment) are all concatenated into a single lookup table before applying to scanned image data for a one-step processing. FIG. 14 illustrates a copier color/image transformation where scanned data 200 is processed by a scanned three-dimensional lookup table at step 202. In step 204, a CLCC three-dimensional lookup table is applied for color adjustment. In step 206, the color data are converted to printer device color space using the printer three-dimensional lookup table which is modified by perceptual adjustment (see FIG. 7). With this process, the three steps of the color transformation can be merged into a single step for faster color transformation.

The entire process for CLCC with perceptual color adjustment in accordance with one embodiment of the present invention is illustrated in FIG. 15. At step 210, perceptual color adjustment is turned off and a pre-defined target is printed. At step 212, the pre-defined target is scanned. In one embodiment, the CLCC lookup table is turned off during this scan. At step 214, a calorimetric CLCC lookup table is generated. Next, at step 216 a perceptual lookup table or function, or select a pre-computed perceptual lookup table is generated. Finally, at step 218, the perceptual lookup table is applied to update the printer three-dimensional lookup table. Alternatively, at step 218 the perceptual lookup table is merged with scanner the three-dimensional lookup table or the printer three-dimensional lookup table.

In embodiments where perceptual adjustment tables are pre-built, the number of tables to be used should be determined. The perceptual adjustment depends on both the original color characteristics and the printing color characteristics. If the source differences are roughly divided into two groups: plain/default and photo/high-quality, and the printing differences are roughly divided into two groups: plain/default and photo media, four pre-built tables will be used.

The subtle differences of different scanner modes can be adjusted to a nominal color state inside the color/imaging ASIC of the copier path to reduce the pre-built perceptual tables (the number of perceptual tables are the multiplication of the number of scanner modes and the number of printer modes). If a printer has many modes, it may be reduce to a few groups, and the subtle differences of different modes can be interpolated among these groups.

In one embodiment of perceptual adjustment, several factors are considered, including: 1) lightness and contrast adjustments; 2) chroma expansion/compression for different hue angles; 3) preference based hue rotation; and 4) rendering intents, such as photo/image intent (perceptual intent), text/computer-graphics (saturation intent) intent.

By adding some color preference adjustment in addition to the calorimetric matching, one embodiment of the present invention improves color quality of the copy path in image systems. In one embodiment, perceptual mapping is simplified by separating perceptual adjustment from the calorimetric mapping.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of color calibration in an image processing system, the method comprising:
printing a target image using pre-defined target image data;
scanning the printed target image;
generating scanned target image data from the scanned target image;
generating a three-dimensional relative calorimetric table from a comparison of the target image data with the scanned target image data;
performing perceptual color adjustment and gamut adjustment to form a color adjustment function; and
updating the three-dimensional relative calorimetric table to reflect the color adjustment function.

2. The method of claim 1 further comprising:
scanning a hardcopy into raw image data of an appropriate format for processing;
performing copier color transformation on the scanned raw image data;
using the three-dimensional relative colorimetric table to convert the scanned raw image data into device data;
converting the device data into printer color space using color adjustment function for printing.

3. The method of claim 2, further including printing the device data.

4. The method of claim 3, wherein scanning a hardcopy includes scanning the hardcopy into an RGB format.

5. The method of claim 3, wherein converting the scanned raw image data includes converting the raw data into a CMYK format.

6. The method of claim 2, wherein performing perceptual color adjustment and gamut adjustment further forms a color adjustment table.

7. The method of claim 7, wherein performing perceptual color adjustment further includes lightness adjustment, chroma adjustment, and hue adjustment.

8. The method of claim 2, wherein performing copier color transformation and generating the three-dimensional relative calorimetric table are done in a single step.

9. An image processing system comprising:
a color printing device configured to print an image using pre-defined target image data;
a scanning color device configured to scan the printed image thereby generating scanned image data; and
a processing device coupled to the scanning color device and the printing color device;
wherein the processing device is configured to generate a three-dimensional relative calorimetric table from a comparison of the target image data with the scanned image data, to generate a color adjustment table based on color preference and the gamut difference between the source hardcopy gamut and the printer gamut, and to concatenate the color adjustment table with the three-dimensional relative calorimetric table to form a perceptually adjusted and gamut adjusted printer table.

10. The system of claim 9, wherein the color scanning device is further configured to scan a hardcopy into raw image data of an appropriate format for processing, wherein the processor is further configured to performing copier color transformation on the scanned raw image data and to use the closed-loop copier color calibration table to convert the scanned raw image data into device data of an appropriate format for printing, and where in the device data is further converted into printer device color space using the perceptually adjusted and gamut adjusted printer table.

11. The system of claim 10, wherein the processing device is further configured to perform both color preference adjustment and gamut adjustment.

12. The system of claim 11, wherein the processing device is further configured to perform lightness adjustment, chroma adjustment, and hue adjustment.

13. The system of claim 12, wherein the color adjustment is processed in a luminance-chrominance color space, including CIE LAB, CIE Luv, CIECAM07s JAB, and CIECMA02 JAB color space.

14. A method of color calibration in an image processing system, the method comprising:
turning off color adjustment and printing a target image using pre-defined target image data;
scanning the printed target image;
generating scanned target image data from the scanned target image;
generating a three-dimensional relative colorimetric table from a comparison of the target image data with the scanned target image data;
performing perceptual color adjustment and gamut adjustment to form perceptual adjusted data;
concatenating the perceptual adjusted data with the three-dimensional relative calorimetric table to form a perceptually adjusted and gamut adjusted printer table;
scanning a hardcopy into raw image data;
performing copier color transformation on the raw image data;
using the three-dimensional relative colorimetric table to convert the raw image data into device data for printing, and
converting the device data into printer device color space using the perceptually adjusted and gamut adjusted printer table.

15. The method of claim 14, further including printing the device data.

16. The method of claim 15, wherein scanning the raw image data includes scanning the raw data into an RGB format.

17. The method of claim 14, wherein performing color adjustment further includes both color preference adjustment and gamut adjustment.

18. The method of claim 17, wherein performing color preference adjustment further includes lightness adjustment, chroma adjustment, and hue adjustment.

19. The method of claim 14, wherein performing copier color transformation on the raw image data and using the three-dimensional relative calorimetric table to convert the raw image data into device data for printing are done in separate steps.

20. The method of claim 14, wherein performing copier color transformation on the raw image data and using the three-dimensional relative calorimetric table to convert the raw image data into device data for printing are done in a single step.
